(19) United States
(12) Patent Application Publication
(10) Pub. No.: US 2018/0097100 A1
(43) Pub. Date: Apr. 5, 2018

(54) MANUFACTURE METHOD OF ARRAY SUBSTRATE

(71) Applicant: Wuhan China Star Optoelectronics Technology Co., Ltd., Wuhan, Hubei (CN)

(72) Inventor: Zhandong ZHANG, Shenzhen, Guangdong (CN)

(73) Assignee: Wuhan China Star Optoelectronics Technology Co., Ltd., Wuhan, Hubei (CN)

(21) Appl. No.: 15/109,341

(22) PCT Filed: May 4, 2016
(86) PCT No.: PCT/CN2016/081040

§ 371 Date: Jun. 30, 2016

(30) Foreign Application Priority Data
Feb. 1, 2016 (CN) 201610068636.9

(51) Int. Cl. H01L 29/786; H01L 21/20; H01L 21/28; G02F 1/136; H01L 21/311

(52) U.S. Cl. CPC H01L 29/786; H01L 21/20; H01L 21/311; G02F 1/136; H01L 21/28

(57) ABSTRACT

The present invention provides a manufacture method of an array substrate, comprising steps of: depositing an active layer including amorphous silicon on a substrate; covering the active layer with a SiOx thin film; converting the amorphous silicon in the active layer into polysilicon; etching the active layer to form a pattern; implanting ion into the active layer; cleaning and removing the SiOx thin film. In the present invention, first, the SiOx thin film covers the active layer, and then processes of the conversion from amorphous silicon into polysilicon, etching the active layer and ion implantation are performed. After the ion is implanted into the active layer, the SiOx thin film is removed so that the active layer is always in the state covered by the thin film in the process to realize the technical result of reducing the pollution to the active layer.

### CROSS REFERENCE

This application claims the priority of Chinese Patent Application No. 201610068636.9, entitled “Manufacture method of array substrate”, filed on Feb. 1, 2016, the disclosure of which is incorporated herein by reference in its entirety.

### FIELD OF THE INVENTION

The present invention relates to a liquid crystal display manufacture field, and more particularly to a manufacture method of an array substrate.

### BACKGROUND OF THE INVENTION

The display panel manufactured with Low Temperature Polysilicon (LTPS) possesses advantages of high resolution, fast response speed, high brightness and high aperture ratio, and with the property of LTPS, it has the high electron mobility; besides, the peripheral driving circuit can be manufactured on the glass substrate at the same time to achieve the objective of the system integration to save the space and the cost of the driving IC, and to reduce the product defect rate.

In the manufacture process of the LTPS TFT array substrate, for raising the TFT property, the ion implantation to the active layer is an indispensable and important step. In the manufacture process of the LTPS TFT array substrate according to prior art, first it needs to deposit a buffer layer on the glass substrate, and then to deposit amorphous silicon a-Si on the entire surface of the buffer layer. The polysilicon layer is formed with the dehydrogenation process and low temperature crystallization process. After the crystallization is finished, a mask is employed to perform pattern exposure, development, etching and stripping to the active layer to form the active layer, and then the ion implantation is performed to the active layer.

In prior art, as performing the ion implantation, for protecting the surface of the active layer from damage due to the ion implantation bombard, the photoresist is generally coated on the surface of the active layer to protect the surface, and the implanted ion passes through the photoresist, and enters the active layer, and ultimately to achieve the ion implantation result. However, in the process from deposition of amorphous silicon a-Si to the formation of the active layer, the silicon layer is in the state of exposure, which will cause the certain ion pollution to the silicon layer. Besides, the photoresist itself also will cause the certain pollution to the silicon layer. It can seriously influence the quality and the process yield of the array substrate, and the manufacture according to prior art is urgent for improvement.

### SUMMARY OF THE INVENTION

An objective of the present invention is to provide a manufacture method of an array substrate, and the method can reduce the pollution to the array substrate in the manufacture process to raise the quality and process yield of the array substrate.

For realizing the aforesaid objective, the technical solution provided by the embodiments of the present invention is:

The present invention provides a manufacture method of an array substrate, comprising steps of: depositing an active layer including amorphous silicon on a substrate; covering the active layer with a SiOx thin film; converting the amorphous silicon in the active layer into polysilicon; etching the active layer to form a pattern; implanting ion into the active layer; cleaning and removing the SiOx thin film.

A thickness of the SiOx thin film is smaller than 100 nm.

The SiOx thin film covers on the active layer with chemical vapor deposition.

Hydrofluoric acid clean is employed to remove the SiOx thin film.

A concentration of hydrofluoric acid is smaller than 5%.

An implantation direction of ion is perpendicular with a plane where the substrate is.

The step of converting the amorphous silicon in the active layer into polysilicon comprises: employing Excimer Laser Annealing or Solid Phase Crystallization to convert the amorphous silicon in the active layer into polysilicon.

XeCl laser is employed to perform laser annealing to the active layer.

The step of depositing an active layer including amorphous silicon on a substrate comprises: providing a base substrate; forming a buffer layer on the base substrate; forming the active layer on the buffer layer.

The buffer layer is formed on the base substrate with chemical vapor deposition or sputtering.

The embodiments of the present invention have advantages or benefits:

In the manufacture method of the array substrate according to the present invention, first, the SiOx thin film covers the active layer, and then processes of the conversion from amorphous silicon into polysilicon, etching the active layer and ion implantation are performed. After the ion is implanted into the active layer, the SiOx thin film is removed so that the active layer is always in the state covered by the thin film in the process to realize the technical result of reducing the pollution to the active layer.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a flowchart of a manufacture method of an array substrate according to the present invention;

FIG. 2 is a structure diagram of an array substrate according to the present invention after a SiOx thin film covers;

FIG. 3 is a structure diagram of an array substrate according to the present invention after polysilicon conversion is accomplished;

FIG. 4 is a structure diagram of an array substrate according to the present invention after etching;

FIG. 5 is a structure diagram of an array substrate according to the present invention after ion implantation;

FIG. 6 is a structure diagram of an array substrate according to the present invention after the SiOx thin film is removed.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

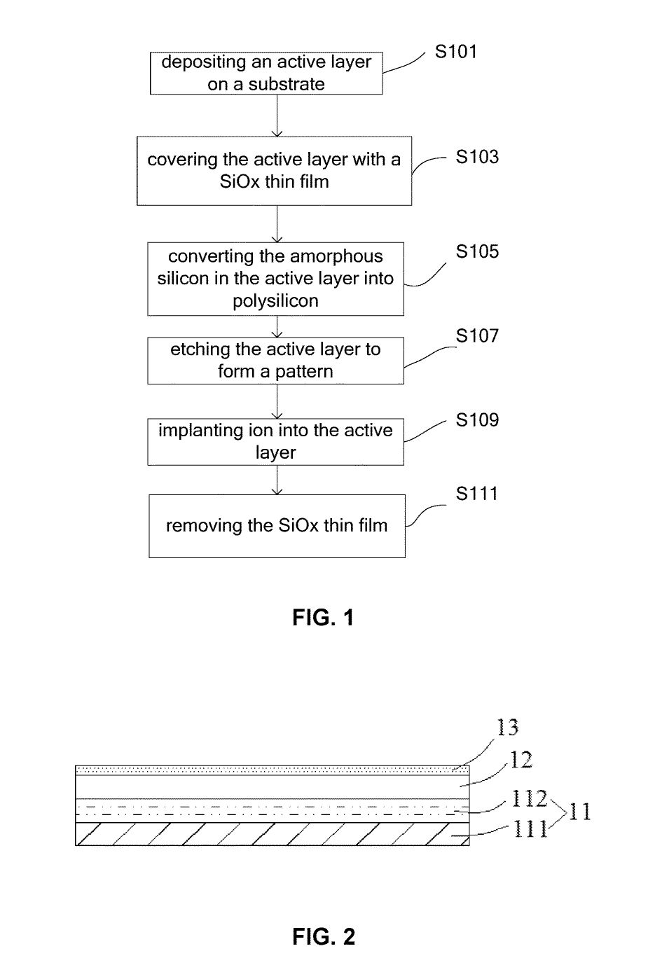

The present invention provides a manufacture method of an array substrate. Please refer to FIG. 1. FIG. 1 is a flowchart of a manufacture method of an array substrate according to the present invention.

Step S101: first, depositing an active layer 12 on a substrate 11, and the active layer 12 comprises amorphous silicon.

The active layer 12 comprises amorphous silicon a-Si. The substrate 11 comprises a base substrate 111 and a buffer layer 112, and for preventing the bad influence generated by the toxic substance in the base substrate 111 (which is generally the glass material) to the active layer 12, it is required to form a buffer layer 112 on the base substrate 111 with PECVD, low-pressure chemical vapor deposition (LPCVD), atmospheric pressure chemical vapor deposition (APCVD), Electron cyclotron resonance chemical vapor deposition (ECR-CVD) or sputtering for blocking that the diffusion of impurity in the glass enters the active layer 12. Besides, before depositing the buffer layer 112, it is required to perform the pre-clean to the base substrate 111 to raise the cleanliness of the base substrate 111.

Furthermore, the material of the buffer layer 112 can be selected from oxide, nitride or oxynitride. The buffer layer 112 can be a single layer, a double layer or a multiple layer structure. Specifically, the buffer layer 112 can be SiNx, SiOx or Si(ON)x.

Step S103: and then covering the active layer 12 with a SiOx thin film 13.

Specifically, referring to FIG. 2, the SiOx thin film 13 covers on the active layer 12 with chemical vapor deposition so that the active layer 12 is isolated from the outside to prevent the ion outside causes pollution to the active layer 12. Furthermore, for ensuring the following process quality, the thickness of the SiOx thin film 13 cannot be over large. Preferably, a thickness of the SiOx thin film 13 is smaller than 100 nm.

Step S105: then, converting the amorphous silicon in the active layer 12 into polysilicon.

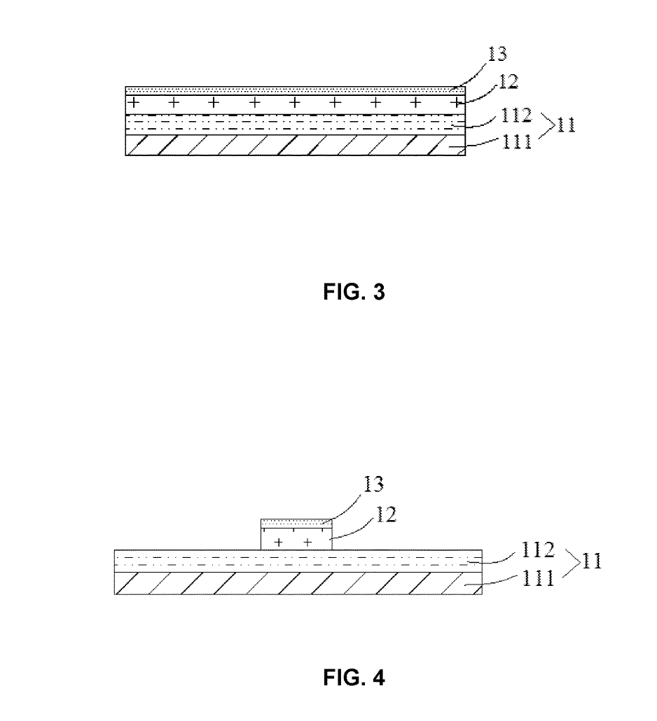

Please refer to FIG. 3. Specifically, the conversion of amorphous silicon a-Si in the active layer 12 into polysilicon poly-Si can be derived with Excimer Laser Annealing (ELA) or Solid Phase Crystallization (SPC). As utilizing the Excimer Laser Annealing, the common Excimer Laser can be XeCl laser, ArF laser, KrF laser and XeF laser. Such kind of Excimer Laser generates the laser beam of ultraviolet band. The short pulse laser beam of ultraviolet band irradiates the amorphous silicon in the active layer 12, and the amorphous silicon will rapidly absorb the laser energy and melts and recrystallizes. The laser can directly irradiates on the surface of the SiOx thin film 13, which is equivalent to directly irradiate on the active layer 12 because the thickness of the SiOx thin film 13 is small. Therefore, the result of the Excimer Laser Annealing is better. It should be explained that The Excimer Laser is employed to irradiate the active layer 12, and also to irradiate on the base substrate 111. The present invention has not specific restriction thereto but it can be decided according to the practical requirement.

Preferably, the laser can be utilized in this step includes: ArF, KrF and XeCl, of which the corresponding laser wavelengths are 193 nm, 248 nm and 308 nm, and the pulse width is 10-50 ns. Preferably, because the laser wavelength of the XeCl laser is longer, and the laser energy can implant into the amorphous silicon deeper, and the crystallization result is better, and thus the XeCl laser is preferably utilized.

Certainly, other methods can be employed in the annealing process of the present invention. The Metal-Induced Crystallization (MIC) can be an illustration.

Step S107: next, etching the active layer to form a pattern.

Specifically, after the polysilicon layer is obtained with the crystallization, the active layer mask is employed to perform exposure, development, etching and stripping to the active layer 12 to form the pattern of the mask on the active layer 12 (as shown in FIG. 4).

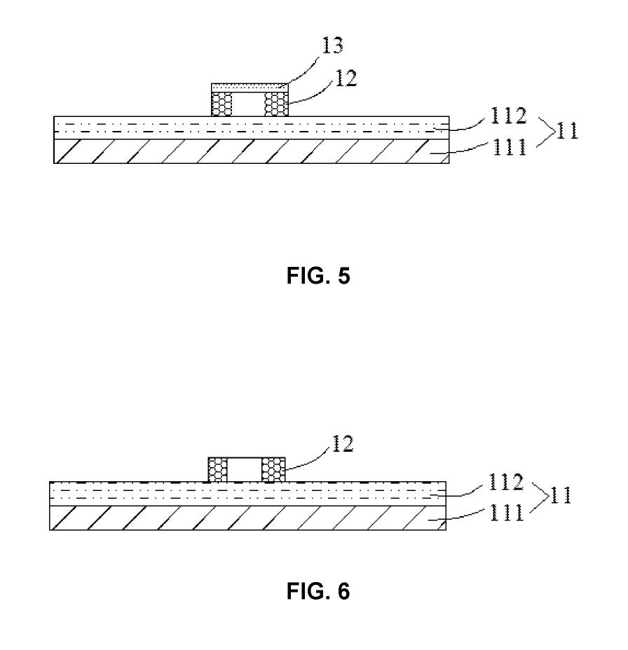

step S109: moreover, referring to FIG. 5, implanting ion into the active layer 12.

The ion in the ion implantation can be one or more of: B ion, P ion, As ion and PHx ion. The ion implantation is a common doping skill. The ion implantation can utilize the ion implantation with the mass-synchrometer, the ion cloud injection method without the mass-synchrometer, plasma implantation or solid state diffusion implantation. In this embodiment, the ion cloud implantation method is utilized. Preferably, an implantation direction of ion is perpendicular with a plane where the substrate is.

Step S111, finally, cleaning and removing the SiOx thin film 13.

Specifically, referring to FIG. 6, after the ion implantation is accomplished, it is also required to cover an isolation layer. After the ion implantation, the SiOx thin film 13 is no longer necessary, and should be removed. Then, the low intensity hydrofluoric acid (DHF) can be used to wash the SiOx thin film 13. Generally, before covering the isolation layer, it will be required to wash the array substrate with hydrofluoric acid. Thus, no additional process is added to the manufacture method of the present invention. Preferably, a concentration of hydrofluoric acid should be smaller than 5% in advance.

After accomplishing the aforesaid steps, the operation of covering the isolation layer on the active layer 12 and the buffer layer 112 can be performed.

In the manufacture method of the array substrate according to the present invention, first, the SiOx thin film covers the active layer, and then processes of the conversion from amorphous silicon into polysilicon, etching the active layer and ion implantation are performed. After the ion is implanted into the active layer, the SiOx thin film is removed so that the active layer is always in the state covered by the thin film in the process to realize the technical result of reducing the pollution to the active layer.

In the description of the present specification, the reference terms, “one embodiment”, “some embodiments”, “an illustrative embodiment”, “an example”, “a specific example”, or “some examples” mean that such description combined with the specific features of the described embodiments or examples, structure, material, or characteristic is included in the utility model of at least one embodiment or example. In the present specification, the terms of the above schematic representation do not certainly refer to the same embodiment or example. Meanwhile, the particular features, structures, materials, or characteristics which are described may be combined in a suitable manner in any one or more embodiments or examples.

Above are embodiments of the present invention, which does not limit the scope of the present invention. Any modifications, equivalent replacements or improvements within the spirit and principles of the embodiment described above should be covered by the protected scope of the invention.

What is claimed is:

1. A manufacture method of an array substrate, comprising steps of: depositing an active layer including amorphous silicon on a substrate; covering the active layer with a SiOx thin film; converting the amorphous silicon in the active layer into polysilicon; etching the active layer to form a pattern; implanting ion into the active layer; cleaning and removing the SiOx thin film.

2. The manufacture method of the array substrate according to claim 1, wherein the SiOx thin film covers on the active layer with chemical vapor deposition.

3. The manufacture method of the array substrate according to claim 1, wherein a thickness of the SiOx thin film is smaller than 100 nm.

4. The manufacture method of the array substrate according to claim 3, wherein the SiOx thin film covers on the active layer with chemical vapor deposition.

5. The manufacture method of the array substrate according to claim 1, wherein hydrofluoric acid clean is employed to remove the SiOx thin film.

6. The manufacture method of the array substrate according to claim 6, wherein a concentration of hydrofluoric acid is smaller than 5%.

7. The manufacture method of the array substrate according to claim 1, wherein an implantation direction of ion is perpendicular with a plane where the substrate is.

8. The manufacture method of the array substrate according to claim 1, wherein the step of converting the amorphous silicon in the active layer into polysilicon comprises: employing Excimer Laser Annealing or Solid Phase Crystallization to convert the amorphous silicon in the active layer into polysilicon.

9. The manufacture method of the array substrate according to claim 8, wherein XeCl laser is employed to perform laser annealing to the active layer.

10. The manufacture method of the array substrate according to claim 1, wherein the step of depositing an active layer including amorphous silicon on a substrate comprises: providing a base substrate; forming a buffer layer on the base substrate; forming the active layer on the buffer layer.

11. The manufacture method of the array substrate according to claim 10, wherein the buffer layer is formed on the base substrate with chemical vapor deposition or sputtering.
